(19) United States
(12) Patent Application Publication
(10) Pub. No.: US 2025/0390651 A1
(43) Pub. Date: Dec. 25, 2025

(54) UPDATING PREDICTION STATE DATA FOR PREDICTION CIRCUITRY

(71) Applicant: Arm Limited, Cambridge (GB)

(72) Inventors: Rami Mohammad AL SHEIKH, Morrisville, NC (US); Houdhaifa BOUZGUARROU, Austin, TX (US)

(21) Appl. No.: 18/753,733

(22) Filed: Jun. 25, 2024

(51) Int. Cl. G06F 30/323

(52) U.S. Cl. CPC G06F 30/323

(57) ABSTRACT

An apparatus is provided comprising prediction state storage circuitry to maintain a set of prediction state data and prediction circuitry configured to generate predictions in pipeline stages. The prediction circuitry is configured to, in a preliminary pipeline stage, generate a preliminary prediction depending on a subset of the prediction state data for use by at least one other component, and in a subsequent pipeline stage, to generate a subsequent prediction depending on the set of the prediction state data. The apparatus further comprises overriding circuitry responsive to a determination that the preliminary prediction and subsequent prediction are different to cause the at least one other component to use the subsequent prediction instead of the preliminary prediction and state update circuitry configured to apply, in response to detecting a divergence-triggered update condition being satisfied, a divergence-triggered update to the subset of the prediction state data.

### BACKGROUND

The present technique relates to the field of data processing and in particular to prediction circuitry.

Some data processing apparatuses comprise prediction circuitry to predict a processing behaviour associated with processing of a given computer program, so that additional functions dependent on the predicted behaviour can be performed speculatively, thus preventing those functions from stalling. The prediction may be based on prediction state data that may be indicative of an outcome of a similar scenario that had been encountered before. The prediction state data is therefore updated as predictions are made and the corresponding outcomes are evaluated, to improve the likelihood that the prediction state data will produce useful predictions.

### SUMMARY

At least some examples of the present technique provide an apparatus comprising: prediction state storage circuitry to maintain a set of prediction state data; prediction circuitry configured to: in a preliminary pipeline stage, generate a preliminary prediction associated with a given memory address in dependence on a subset of the prediction state data and to provide the preliminary prediction for use by at least one other component, and in a subsequent pipeline stage, generate a subsequent prediction associated with the given memory address in dependence on the set of the prediction state data; overriding circuitry responsive to a determination that the subsequent prediction is different from the preliminary prediction to cause the at least one other component to use the subsequent prediction instead of the preliminary prediction; and state update circuitry configured to apply, in response to detecting a divergence-triggered update condition being satisfied, a divergence-triggered update to the subset of the prediction state data used to generate the preliminary prediction, wherein the divergence-triggered update condition being satisfied is dependent on the subsequent prediction being different from the preliminary prediction.

At least some examples of the present technique provide a system comprising: an apparatus as described above implemented in at least one packaged chip; at least one system component; and a board; wherein the at least one packaged chip and the at least one system component are assembled on the board.

At least some examples of the present technique provide a chip-containing product comprising the system described above, wherein the system is assembled on a further board with at least one other product component.

At least some examples of the present technique provide a method comprising: maintaining a set of prediction state data; generating, in a preliminary pipeline stage, a preliminary prediction associated with a given memory address in dependence on a subset of the prediction state data and to provide the preliminary prediction for use by at least one other component, and generating, in a subsequent pipeline stage, a subsequent prediction associated with the given memory address in dependence on the set of the prediction state data; causing, in response to a determination that the subsequent prediction is different from the preliminary prediction, the at least one other component to use the subsequent prediction instead of the preliminary prediction; and applying, in response to detecting a divergence-triggered update condition being satisfied, a divergence-triggered update to the subset of the prediction state data used to generate the preliminary prediction, wherein the divergence-triggered update condition being satisfied is dependent on the subsequent prediction being different from the preliminary prediction.

At least some examples of the present technique provide a non-transitory computer-readable medium storing computer-readable code for fabrication of an apparatus comprising: prediction state storage circuitry to maintain a set of prediction state data; prediction circuitry configured to: in a preliminary pipeline stage, generate a preliminary prediction associated with a given memory address in dependence on a subset of the prediction state data and to provide the preliminary prediction for use by at least one other component, and in a subsequent pipeline stage, generate a subsequent prediction associated with the given memory address in dependence on the set of the prediction state data; overriding circuitry responsive to a determination that the subsequent prediction is different from the preliminary prediction to cause the at least one other component to use the subsequent prediction instead of the preliminary prediction; and state update circuitry configured to apply, in response to detecting a divergence-triggered update condition being satisfied, a divergence-triggered update to the subset of the prediction state data used to generate the preliminary prediction, wherein the divergence-triggered update condition being satisfied is dependent on the subsequent prediction being different from the preliminary prediction.

Further aspects, features and advantages of the present technique will be apparent from the following description of examples, which is to be read in conjunction with the accompanying drawings.

### BRIEF DESCRIPTION OF THE DRAWINGS

FIG. 1 schematically illustrates an example of a data processing apparatus;

FIG. 2 illustrates an example of pipeline stages for a pipelined predictor;

FIG. 3 illustrates an example of a pipelined TAGE predictor;

FIG. 4 illustrates an example predictor apparatus;

FIG. 5 illustrates an example of steps for operating a pipelined predictor and applying a divergence-triggered update;

FIG. 6 illustrates an example of steps for evaluating a divergence-triggered update condition;

FIG. 7 illustrates an example of steps for performing a probabilistic test;

FIG. 8 illustrates a specific example of a TAGE predictors;

FIG. 9 illustrates a specific example of a perceptron predictor;

FIG. 10 illustrates an example of steps for applying a divergence-triggered update before an actual outcome is known;

FIGS. 11A and 11B illustrate an example of steps for applying a divergence-triggered update after an actual outcome is known;

FIG. 12 illustrates a system and a chip-containing product.

### DESCRIPTION OF EXAMPLES

In accordance with some example embodiments, there is provided an apparatus comprising prediction state storage circuitry to maintain a set of prediction state data; prediction circuitry configured to: in a preliminary pipeline stage, generate a preliminary prediction associated with a given memory address in dependence on a subset of the prediction state data and to provide the preliminary prediction for use by at least one other component, and in a subsequent pipeline stage, generate a subsequent prediction associated with the given memory address in dependence on the set of the prediction state data; and overriding circuitry responsive to a determination that the subsequent prediction is different from the preliminary prediction to cause the at least one other component to use the subsequent prediction instead of the preliminary prediction.

Such a pipelined approach to prediction allows the at least one other component to use the preliminary prediction more quickly, with a trade-off being that the preliminary prediction may be less accurate due to only being based on a subset of the prediction state data. In a later pipeline stage the subsequent prediction, which is likely to be more accurate, can be used instead of the preliminary prediction if a prediction divergence has occurred (i.e. if the subsequent prediction is different to the preliminary prediction). One problem with this approach is that when an override does occur, a ‘bubble’ is created in the prediction pipeline, for example due to flushing any instructions or results that were based on the preliminary prediction. On each occurrence of a pipeline bubble, there can be a cost to performance in terms of both processing performance and power consumption.

In accordance with the present techniques, the apparatus is provided with state update circuitry configured to apply, in response to detecting a divergence-triggered update condition being satisfied, a divergence-triggered update to the subset of the prediction state data used to generate the preliminary prediction, wherein the divergence-triggered update condition being satisfied is dependent on the subsequent prediction being different from the preliminary prediction. The specific information that the divergence-triggered update is based on may vary. For example, the divergence-triggered update may cause the subset of the prediction state data to reflect the subsequent prediction or to reflect an actual resolved outcome associated with the given memory address. Either way, updating the state information used for the preliminary prediction in cases where divergence between the preliminary prediction and subsequent prediction is detected can make it more likely that, in future, the preliminary prediction is the same as the subsequent prediction, thereby reducing the likelihood of a prediction divergence and pipeline bubbles. This solution is counterintuitive because in typical prediction algorithms any updates triggered based on whether a final prediction (e.g. the subsequent prediction) is determined to be correct would apply the prediction state updates to the state used for the final prediction actually used to control subsequent behaviour at the at least one component (which would be the state used in the subsequent prediction in cases where the subsequent prediction diverges from the preliminary prediction). In contrast, the inventors have realised that in the specific case of prediction circuitry configured to generate predictions in pipelined stages, applying the divergence-triggered update to the prediction state data used for the preliminary prediction can improve processing performance and power efficiency by reducing frequency of pipeline bubbles caused by the subsequent prediction overriding the preliminary prediction.

Although the divergence-triggered update can improve the accuracy of the preliminary predictions, in some examples it may not be useful to do so every time the prediction divergence occurs. For example, an item of state used to make the preliminary prediction for one memory address could be shared with other addresses, and so there could be a possibility that the divergence-triggered update made for a prediction based on one address could sometimes harm prediction accuracy for other addresses sharing the same prediction state. Hence, the divergence-triggered update condition being satisfied may be further dependent on a predetermined outcome arising from a probabilistic test having a given probability of providing the predetermined outcome. Therefore, among the occasions where the subsequent prediction is different to the preliminary prediction, the divergence-triggered update has a given probability of being applied. In some examples, the given probability is set such that the probabilistic test results in the predetermined outcome in a minority of cases (e.g. the probability could be less than 50%, but may be as low as 15% or 5%). By not applying the divergence-triggered update every time divergence between the preliminary and subsequent predictions is detected, and instead applying the update a certain fraction of the times that such divergence is detected, this can give better performance overall, as the addresses for which frequent divergence is encountered between preliminary and subsequent predictions occur can have more “attempts” at satisfying the probabilistic test and are more likely eventually to succeed in applying the divergence-triggered update to improve performance by reducing the likelihood of bubbles caused by such divergent predictions. On the other hand, addresses which rarely see divergence between preliminary and subsequent predictions (and so do not suffer from many “bubbles” being introduced) are less likely to apply the divergence-triggered update even if there is an isolated occasion when such divergence occurs, to reduce risk of the divergence-triggered updates disrupting prediction accuracy for that address or other addresses sharing the same prediction state.

The probabilistic test may be implemented in various ways. In some examples, the probabilistic test is analogous to a dice roll to produce a random or pseudo-random number, where the predetermined outcome occurs when the number equals a particular value or is above or below a particular threshold. The number may be generated by a random or pseudorandom number generator (e.g. a linear feedback shift register), or in dependence on sampling of some bits of information or signals elsewhere in the system (which may not necessarily be related to the prediction circuitry).

In other examples, the state update circuitry comprises a counter and the probabilistic test comprises determining whether the test counter has a predetermined value. Therefore, on each occurrence of a prediction divergence the state update circuitry may evaluate the value of the test counter and, if it has the predetermined value, the probabilistic test is determined to have provided the predetermined outcome. The test counter can be incremented in response to occurrences of a particular event. In some examples, the test counter is incremented each time a prediction is made. In other examples, the test counter is incremented in response to the determination of the prediction divergence between the preliminary and subsequent predictions. Hence, it may be a matter of probability whether, on a given instance of detecting divergence between the preliminary and subsequent predictions, the test counter has the predetermined value, and by controlling the number of increments taken between successive instances when the test counter has the predetermined value, the probability of the probabilistic test giving the predetermined outcome can be controlled.

In some examples, the given probability of the probabilistic test resulting in the predetermined outcome is fixed.

In other examples, the given probability resulting in the predetermined outcome is dynamically adjustable.

For example, the impact of the divergence-triggered updates on the performance of the prediction circuitry, both in terms of accuracy and frequency of pipeline bubbles can be monitored. If it is determined that the frequency of divergence-triggered updates is detrimental to performance then the given probability can be reduced. On the other hand, if it is determined that the frequency of divergence-triggered updates is improving performance then the given probability can be increased.

In some examples, the given probability may be dynamically adjustable depending on a rate of updates to the prediction state data triggered based on detection that the subsequent prediction is incorrect. This can be helpful because if the rate of updates to the prediction state data (e.g. rate of allocations of new entries to prediction state tables) is high, this can indicate that the final subsequent prediction is more likely to be incorrect and so even if there is divergence between preliminary and subsequent predictions, it is uncertain whether it is really justified to update the preliminary prediction’s state data. Hence, overall prediction accuracy (and hence processing performance) may be greater if the given probability is lower (or even reduced to zero) in cases where the rate of updates to the prediction state data triggered based on detection that the subsequent prediction is incorrect exceeds a given threshold, and higher in cases where the rate of updates is less than the given threshold.

In some examples of the present techniques, the prediction circuitry is configured to generate the subsequent prediction on the subset of the prediction state data and on at least some of the set of the prediction state data that is not in the subset. Accordingly, the subsequent prediction takes into account more prediction state data in addition to the prediction state data that was used to generate the preliminary prediction. It is therefore expected that, in such examples, the subsequent prediction is more likely to be of higher accuracy than the preliminary prediction due to being based on more prediction state data. However, considering a greater amount of prediction state data can require more complex prediction logic which may make it harder to meet timing constraints within the number of cycles within which the preliminary prediction is feasible, and so this means at least one further pipeline stage may be used to provide the subsequent prediction beyond the pipeline stage in which the preliminary prediction is available. Hence, it can be useful to apply the divergence-triggered updates as explained above to reduce the frequency of pipeline bubbles caused by the preliminary prediction being overridden by the subsequent prediction, which might otherwise waste power (in additional wasted cycles of looking up the prediction for the address determined based on the preliminary prediction) and reduce processing performance.

In examples described here, the divergence-triggered update can be applied even when the subsequent prediction is determined to be correct. This may be counter-intuitive, since if the subsequent prediction is correct one would expect that there is no need to change the prediction state, as there would have been no need to trigger a pipeline flush or other misprediction recovery operation if the subsequent prediction is correct. However, it is recognised that even if the subsequent prediction is correct, the divergence between the preliminary and subsequent predictions means there was at least one pipeline bubble which may have caused additional power consumption at the prediction circuitry and reduced processing performance, so it can be useful to update the prediction state to try to reduce the likelihood of that divergence occurring again in future.

The present technique may be applied to various specific types of prediction circuitry, so is not necessarily limited to any particular type of prediction circuitry that uses pipelined predictions.

In some examples, the prediction circuitry comprises a tagged geometric length (TAGE) predictor where the set of prediction state data comprises a plurality of prediction tables associated with varying lengths of program flow history. In a TAGE predictor, the prediction tables represent prediction state data where the prediction depends on the preceding program flow history (e.g. information on a sequence of preceding branch instructions that led to making a current prediction). Furthermore, the prediction may vary depending on the length of the program flow history, such that a prediction based on more recent program flow history (i.e. shorter history length) may be different to that based on a less recent program flow history (i.e. longer history length). The prediction tables comprise short-history prediction tables associated with a shorter history length and long-history prediction tables associated with a longer history length. Therefore, when generating a prediction based on a shorter history, a lookup is performed in the short-history tables and when generating a prediction based on a longer history, a lookup is performed in the long-history tables.

When a TAGE predictor is pipelined as described above, the prediction circuitry may generate the preliminary prediction in dependence on a hit on a preliminary entry in a short-history prediction tables. Accordingly, only some (i.e. not all) of the prediction tables are looked up when generating the preliminary prediction. This allows for the preliminary prediction to be generated more quickly and provided for use by the at least one other component as described previously. The prediction circuitry then generates the subsequent prediction in dependence on a hit in any of the short-history tables and the long-history tables, which may require more complex logic (hence using at least one further pipeline stage) to combine and decide the outcome of the subsequent prediction. In some examples, all of the prediction tables are looked up when generating the subsequent prediction.

In general, a prediction based on a longer history length is more likely to be accurate (in comparison to a prediction based on shorter history length) in cases where a hit is detected in a table based on longer history length. Therefore when generating the subsequent prediction, the prediction circuitry is configured to prioritise a hit in a long-history prediction table over a hit in a short-history prediction table.

In the event that the subsequent prediction is generated based on a hit in a long-history prediction table (i.e. a prediction that was not looked up for generating the preliminary prediction), then there is a possibility that the subsequent prediction would be different to the preliminary prediction thus causing a prediction divergence as described above. In accordance with the present techniques, if the divergence-triggered update condition is satisfied as described above, the state update circuitry is configured to apply the divergence-triggered update to the preliminary entry in the one or more short-history prediction tables. This is particularly counter-intuitive in the context of TAGE predictors, since the divergence-triggered update causes a short-history prediction table to be updated even though the actual prediction used to control the at least one component was based on an entry corresponding to a longer history length used to make the subsequent prediction. Such a divergence-triggered update to the preliminary entry in the short-history prediction tables would appear to violate the TAGE update algorithm, so would be seen as extremely counter-intuitive by a skilled person in the field. However, as noted above, applying the divergence-triggered update in this way reduces the likelihood of a prediction divergence and hence reduces the likelihood of predictor pipeline bubbles.

In the event that the subsequent prediction is determined to be incorrect, a misprediction-triggered update may be applied, for example, to update the subsequent entry based on an actual outcome. In some examples, if the divergence-triggered update condition is satisfied while it is determined that the subsequent prediction is determined to be incorrect, the state update circuitry may apply two updates including both the divergence-triggered update to the preliminary entry and the misprediction-triggered update to the subsequent entry.

As described above, the present technique may be applied to different types of predictors. In some examples, the prediction circuitry comprises a perceptron predictor, which uses a neural network-like algorithm to train a set of prediction state data comprising a plurality of weights. The weights are used to generate a prediction, for example, by summing the weights to compute a prediction value indicative of a prediction. When a perceptron predictor is pipelined as described above, the prediction circuitry uses only a subset (i.e. not all) of the plurality of weights to compute a prediction value for the preliminary prediction. Since not all of the plurality of weights are used, the prediction value can be computed more quickly to allow the at least one other component use the preliminary prediction sooner. The prediction circuitry then generates the subsequent prediction by computing a prediction value based on the plurality of weights (e.g. all of the plurality of weights).

In accordance with the present techniques, if the subsequent prediction is different to the preliminary prediction, a prediction divergence occurs as described above. If the divergence-triggered update condition is satisfied, the state update circuitry applies the divergence-triggered update according to a weight update function applied to the subset of the plurality of weights used to generate the preliminary prediction (excluding the remaining weights that are not used for the preliminary prediction but are used for the subsequent prediction – this differs from the update function which would be applied when the subsequent prediction is incorrect, which would be applied to the set of weights as a whole including the weights used for the subsequent prediction which are not used for the preliminary prediction). The weight update function may vary depending on the particular implementation.

The point in time at which the state update circuitry applies the divergence-triggered update may vary. In some examples, the divergence-triggered update is applied before an actual outcome associated with the given memory address has been determined. This may be referred to as applying the divergence-triggered update at prediction time (i.e. when the subsequent prediction is generated).

Since it is not yet known whether the subsequent prediction is correct at prediction time, the state update circuitry may be further responsive to an indication that the subsequent prediction was incorrect to perform a divergence-triggered remedial action. For example, the prediction state data can be reverted to undo the divergence-triggered update, or a further update can be applied to reflect the actual outcome (i.e. that has been determined to be different to the subsequent prediction).

In other examples, the state update circuitry may omit any divergence-triggered remedial action and instead rely on the prediction state data being corrected over time by misprediction-triggered updates, so in some examples incorrect prediction-time divergence-triggered updates do not necessarily need to be reversed at execution time if the subsequent prediction is determined to be incorrect.

In other examples, the divergence-triggered update is applied after a determination of an actual outcome associated with the given memory address. This may be referred to as applying the divergence-triggered update at execute time (i.e. when the instruction evaluating the outcome has executed by processing circuitry). It would be appreciated that if the actual outcome is determined to be different to the subsequent prediction, but the same as the preliminary prediction, it would not be beneficial to perform the divergence-triggered update such that the preliminary prediction is more likely to be the same as the subsequent prediction, since then the preliminary prediction would also be incorrect. Therefore, in such examples the divergence-triggered update condition being satisfied may be further dependent on the preliminary prediction being different to the actual outcome. Accordingly, if the actual outcome is what was predicted by the preliminary prediction, the divergence-triggered update is not applied.

When a prediction divergence occurs and the preliminary prediction is overridden by the subsequent prediction, the state update circuitry may relocate the entry in the subset of prediction state data that was used to generate the preliminary prediction, to identify the entry to which the divergence-triggered update should be applied. In some examples, the state update circuitry is configured to cause the prediction circuitry to re-generate the preliminary prediction associated with the given memory address (e.g. by repeating a lookup of the prediction circuitry performed for the given memory address). Once an entry has been identified for generating the preliminary prediction, the state update circuitry can then apply the divergence-triggered update to that entry. In other examples, the state update circuitry is configured to store, at prediction time, an indication identifying an entry in the subset of prediction state data to which the divergence-triggered update is to be applied. For example, the indication identifying the entry may be captured in response to the initial lookup of the prediction state information that was performed to generate the preliminary prediction. Accordingly, at execute time, the state update circuitry can use the stored entry identifying information to quickly identify the entry (without needing to repeat a lookup) and apply the divergence-triggered update if required. This can save power by reducing the extent to which tag comparison operations used in the lookup need to be performed again at execute time in an example which applies the divergence-triggered update at execute time.

In some examples, when the overriding circuitry identifies the prediction divergence and causes the subsequent prediction to be used instead of the preliminary prediction, an instruction associated with the given address can be associated with a divergent-prediction tag. The state update circuitry can then monitor for when an instruction associated with a divergent-prediction tag has been executed and the actual outcome has been determined. In this way, the fact that divergence between the preliminary and subsequent predictions was identified at prediction time can be flagged to the logic evaluating prediction outcomes at execute time, with the divergent-prediction tag passing down a processing pipeline along with the corresponding instruction to indicate that, depending on the actual resolved outcome, a divergence-triggered update may be performed on resolving the actual resolved outcome for that instruction.

In some examples, since the actual outcome associated with the given memory address is known after execute time, it would be beneficial to update the subset of prediction state data used for the preliminary prediction to reflect that actual outcome (which may or may not be the same as the subsequent prediction). In doing so, the preliminary prediction may be more accurate in future predictions. Accordingly, in some examples where the divergence-triggered update is applied at execute time (rather than prediction time) the divergence-triggered update may be based on the actual outcome associated with the given memory address.

As described above, the present techniques may be applied to various different types of predictors. The present techniques may also be applied to various different types of information that is being predicted. In some examples, the preliminary prediction and subsequent prediction relate to prediction of a branch outcome direction (e.g. taken or not taken) or prediction of a branch target address. In these examples, an associated instruction would be a branch instruction and the given memory address may be a memory address identified by a program counter value indicating a current point of program flow reached by the (branch) prediction circuitry. In other examples, the preliminary prediction and subsequent prediction relate to a data value, where the given memory address is the memory address of that data value (e.g. data value prediction circuitry may predict the value loaded from memory for the given memory address before that value has actually been returned from memory). For ease of explanation, the following specific examples will primarily relate to predicting branch outcome direction, however it will be appreciated that the present techniques are equally applicable to other types of predictions.

Specific examples are now explained with reference to the drawings.

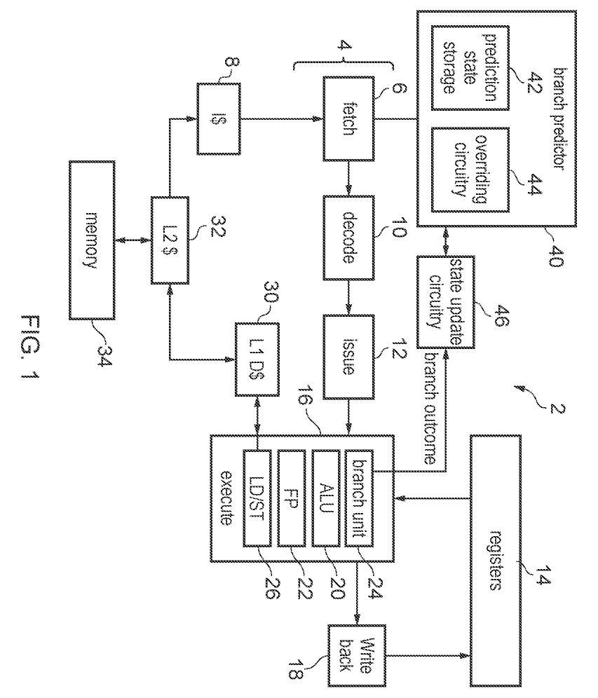

FIG. 1 schematically illustrates an example of a data processing apparatus 2. The data processing apparatus has a processing pipeline 4 which includes a number of pipeline stages. In this example, the pipeline stages include a fetch stage 6 for fetching instructions from an instruction cache 8; a decode stage 10 for decoding the fetched program instructions to generate micro-operations (decoded instructions) to be processed by remaining stages of the pipeline; an issue stage 12 for checking whether operands required for the micro-operations are available in a register file 14 and issuing micro-operations for execution once the required operands for a given micro-operation are available; an execute stage 16 for executing data processing operations corresponding to the micro-operations, by processing operands read from the register file 14 to generate result values; and a writeback stage 18 for writing the results of the processing back to the register file 14. It will be appreciated that this is merely one example of possible pipeline architecture, and other systems may have additional stages or a different configuration of stages. For example in an out-of-order processor a register renaming stage could be included for mapping architectural registers specified by program instructions or micro-operations to physical register specifiers identifying physical registers in the register file 14. In some examples, there may be a one-to-one relationship between program instructions decoded by the decode stage 10 and the corresponding micro-operations processed by the execute stage. It is also possible for there to be a one-to-many or many-to-one relationship between program instructions and micro-operations, so that, for example, a single program instruction may be split into two or more micro-operations, or two or more program instructions may be fused to be processed as a single micro-operation.

The execute stage 16 includes a number of processing units, for executing different classes of processing operation. For example the execution units may include a scalar arithmetic/logic unit (ALU) 20 for performing arithmetic or logical operations on scalar operands read from the registers 14; a floating point unit 22 for performing operations on floating-point values; a branch unit 24 for evaluating the outcome of branch operations and adjusting the program counter which represents the current point of execution accordingly; and a load/store unit 26 for performing load/store operations to access data in a memory system 8, 30, 32, 34.

In this example, the memory system includes a level one data cache 30, the level one instruction cache 8, a shared level two cache 32 and main system memory 34. It will be appreciated that this is just one example of a possible memory hierarchy and other arrangements of caches can be provided. The specific types of processing unit 20 to 26 shown in the execute stage 16 are just one example, and other implementations may have a different set of processing units or could include multiple instances of the same type of processing unit so that multiple micro-operations of the same type can be handled in parallel. It will be appreciated that FIG. 1 is merely a simplified representation of some components of a possible processor pipeline architecture, and the processor may include many other elements not illustrated for conciseness. As shown in FIG. 1, the apparatus 2 includes a branch predictor 40 (an example of the prediction circuitry mentioned above) for predicting outcomes of branch instructions. The branch predictor is looked up based on addresses of instructions to be fetched by the fetch stage 6 and provides a prediction on whether those instructions are predicted to include branch instructions, and for any predicted branch instructions, a prediction of their branch properties such as a branch type, branch target address and branch direction (predicted branch outcome, indicating whether the branch is predicted to be taken or not taken). The branch predictor 40 includes prediction state storage circuitry 42 storing prediction state data for predicting properties of the branches such as branch direction. The branch predictor 40 further includes overriding circuitry 44 capable of identifying whether a preliminary prediction and a subsequent prediction are different (referred to herein as a prediction divergence). If a prediction divergence is identified, the overriding circuitry 44 prevents further use of the preliminary prediction by another component (such as the fetch stage 6, which may be fetching new instructions based on the preliminary prediction), and causes the other component to use the subsequent prediction instead. The particular details of how a preliminary prediction and subsequent prediction are generated will be discussed in more detail later. It will be appreciated that the branch predictor 40 could also include other prediction structures such as a call-return stack for predicting return addresses of function calls, a loop direction predictor for predicting when a loop controlling instruction will terminate a loop, or other more specialised types of branch prediction structures for predicting behaviour of outcomes in specific scenarios.

As shown in FIG. 1, the apparatus 2 further includes state update circuitry 46 which receives signals from the branch unit 24 indicating the actual outcome of instructions, such as indications of whether a taken branch was detected in a given block of instructions, and if so the detected branch type, target address or other properties. If a branch was detected to be not taken then this is also provided to the state update circuitry 46. The state update circuitry 46 updates the prediction state data within the prediction state storage circuitry 42 and other branch prediction structures to take account of the actual results seen for an executed block of instructions, so that it is more likely that on encountering the same block of instructions again then a correct prediction can be made. Also, as noted further below, the state update circuitry 46 can also trigger divergence-triggered updates of prediction state when a divergence-triggered update condition (dependent on the prediction divergence mentioned above) is satisfied, even in cases where the subsequent prediction used to actually control the other component (e.g. fetch stage 6) is correct.

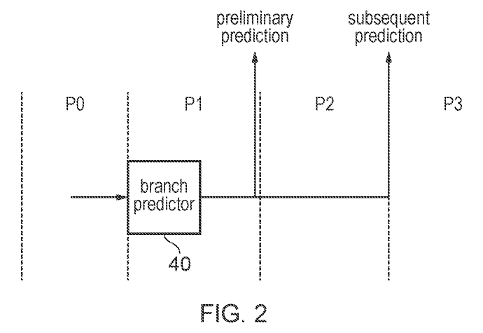

According to the present techniques, the branch predictor 40 is configured to generate predictions in a pipelined arrangement. An example of pipelined predictions is illustrated in FIG. 2 showing pipeline stages P0 to P3. In stage P0, the branch predictor 40 is accessed and then a preliminary prediction is produced in stage P1. The preliminary prediction is generated quickly using only a subset (i.e. not all) of the prediction state data contained in the prediction state storage circuitry 42. The preliminary prediction can be used in cycle P2 by another component. For example, the fetch stage 6 can start issuing fetch requests to memory system to begin fetching instructions based on the preliminary prediction provided in stage P1, resulting in improved performance in the event that the preliminary prediction is correct.

In stage P2, the branch predictor 40 generate a subsequent prediction using the set of prediction state data (i.e. including at least the subset used to generate the preliminary prediction and more prediction state data not used to generate the preliminary prediction). Since the subsequent prediction is generated while taking into account more of the prediction state data, it can be slower to generate (as more complex logic is needed to combine the larger amount of prediction state data, so this is why the subsequent prediction uses an additional clock cycle). However, the subsequent prediction is likely to be more accurate than the preliminary prediction.

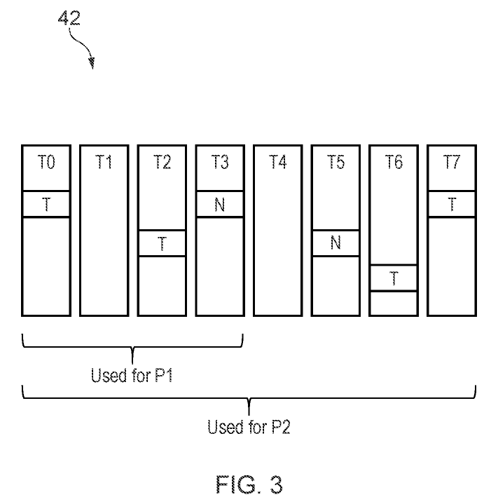

FIG. 3 illustrates a simplified example of using prediction state data in a pipelined arrangement, where the branch predictor comprises a tagged geometric history (TAGE) predictor. In this example, there are 8 prediction tables T0 to T7, where T0 is associated with the shortest history length, T1 is associated with a longer history length, T2 is associated with a still longer history length and so on until T7, which is associated with the longest history length. Each table is looked up based on history information which provides an indication of the program flow history preceding the address for which the prediction is being made. For example, a history buffer may record information about each successive taken branch (e.g. a hash of the branch instruction address and/or branch target address may be pushed into the buffer on each taken branch), so that the history buffer records a sequence of entries representing the most recent N taken branches, which can help distinguish different program flow routes to the same address being predicted in the current cycle. Each table T0 to T7 is looked up based on a portion of the history buffer of successively longer history length, so table T0 is looked up based on history information representing only a short sequence of recent branches, while table T7 is looked up based on history information representing a longer sequence of recent branches. This helps trade off the likelihood of hitting in one of the tables (more likely for lookups based on shorter history) against the likelihood that a hit entry of a given table provides a correct prediction (more likely for lookups based on longer history), to give better performance overall than would be possible for a single table looked up based on a fixed length of history.

Hence, when looking up a TAGE predictor, for each TAGE table T0-T7, a lookup value is determined as a function of the address being looked up and a portion of the history information corresponding to the required history length for that TAGE table, and compared against tags stored in entries of that TAGE table, and if the lookup value matches the stored tag, a hit is detected in that table. If multiple TAGE tables detect a hit against one of its entries, the longer history tables are prioritised over shorter history tables, so that the prediction can be based on the hit entry which is in the TAGE table that, among the tables that encountered a hit, is the one looked up based on the longest length of history.

When generating a preliminary prediction in this example of FIG. 3, a lookup is performed in the prediction tables T0 to T3, resulting in a hit in T0 indicating a prediction of “T” or taken, a hit in T2 indicating a prediction of “T” (taken), and a hit in T3 indicating a prediction of “N” or not taken. Since T3 is associated with a longer history than T0 and T2, the hit in T3 takes priority and the preliminary prediction is generated to predict that a branch is not taken.

When generating a subsequent prediction in this example, a lookup is performed in all of the tables, resulting in the same hits in T0 and T3 as above and an additional hit in tables T5, T6, T7 indicating predictions of “N”, “T” and “T” respectively. Since T7 is associated with a longer history than T0, T2, T3, T5, T6 (tables T1 and T4 being irrelevant for this comparison in this example because they did not detect a hit), the hit in T7 takes priority and the subsequent prediction is generated to predict that a branch is taken.

It will be appreciated that a pipelined branch predictor 40 is not limited to only generating two predictions (i.e. a preliminary prediction and a subsequent prediction). There may be additional pipeline stages, each stage using progressively more of the prediction state data until a final prediction is generated based on all of the prediction state data.

In the example of FIG. 3, a prediction divergence is detected by the overriding circuitry 44 , because the subsequent prediction (taken – T) differs from the preliminary prediction (not taken – N). The overriding circuitry 44 therefore causes any components using the preliminary prediction to use the subsequent prediction instead. Referring back to the previous example of the fetch stage 6, the override circuitry 44 may therefore cause one or more subsequent instruction whose address is predicted based on the subsequent prediction to be cancelled from being fetched (or if already fetched, to flush the one or more subsequent instructions from the pipeline).

If a subsequent prediction overrides a preliminary prediction, then there may be at least one cycle delay in providing the next fetch address to the fetch stage 6 (e.g. the fetch stage 6 cannot begin fetching the next instruction until at least cycle P3, rather than P2), which can cause empty cycles in the pipeline when no instruction is fetched, hence reducing performance. Also, the prediction circuitry 40 may, in cycle P2, already have started looking up its prediction structures for the address of the next instruction that was determined based on the preliminary prediction output in cycle P1, but if the subsequent prediction overrides the preliminary prediction, this lookup in cycle P2 is wasted as the prediction circuitry 40 has to start again with another lookup based on a different address in cycle P3. Hence, although overriding the preliminary prediction with the subsequent prediction ultimately does not cause any problems for correctness of the processing outcomes of the instructions being executed, this nevertheless incurs a power cost because there are more cycles in which the power consumed in looking up the prediction circuitry is wasted.

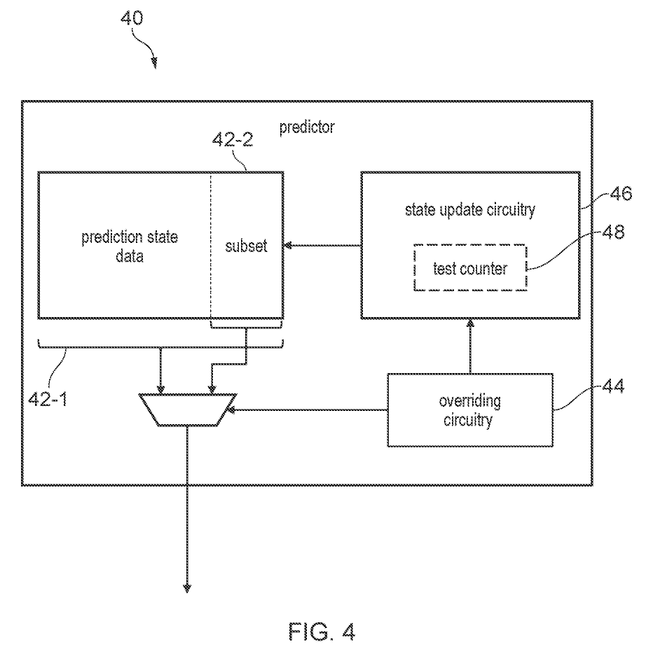

FIG. 4 illustrates an apparatus according to an example of the present techniques. The pipelined prediction process as described above is performed using the subset 42-2 of the prediction state data to form the preliminary prediction in a preliminary pipeline stage and then the full set of prediction state data 42-1 to form the subsequent prediction in a subsequent pipeline stage. The overriding circuitry 44 detects the occurrence of a prediction divergence (when the subsequent prediction is different from the preliminary prediction) and controls which prediction is provided for use by other components as described above.

The apparatus is further provided with state update circuitry 46 configured to receive a signal from the overriding circuitry 44 in response to the occurrence of a prediction divergence for evaluating whether or not a divergence-triggered update condition is satisfied. If so, then the state update circuitry is configured to apply a divergence-triggered update to the subset 42-2 of the prediction state data. By applying the divergence-triggered update to the subset 42-2 of the prediction state data, a preliminary prediction generated based on the subset 42-2 will be more likely to match the subsequent prediction on future attempts at predicting the corresponding address, thus preventing the occurrence of a pipeline bubble. For example, referring back to FIG. 3, the entry hit in table T3 may be updated so that it indicates a prediction “T” or taken (matching the subsequent prediction T based on the hit entry in T7) instead of “N” or not taken.

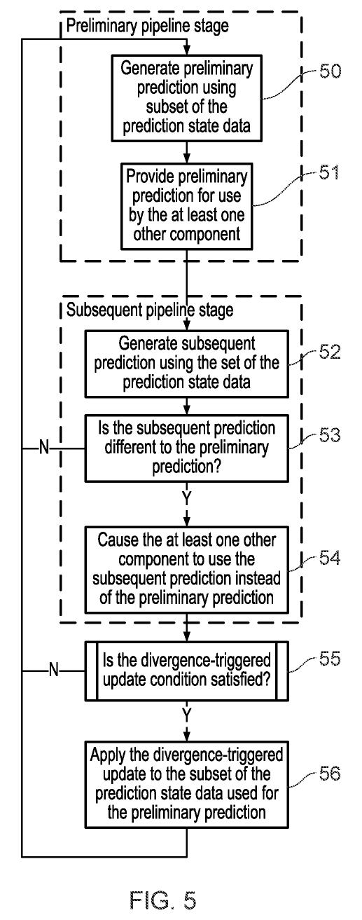

FIG. 5 illustrates an example prediction method. In step 50, a preliminary prediction associated with a given memory address is generated using the subset 42-2 of the prediction state data. In step 51, the preliminary prediction is provided for use by at least one other component. Steps 50 and 51 are performed at the preliminary pipeline stage (e.g. stage P1 of FIG. 2). In step 52, which occurs in the subsequent pipeline stage (e.g. stage P2 of FIG. 2), the subsequent prediction is generated using the set of the prediction state data 42-1. The subsequent prediction is associated with the same given memory address used to generate the preliminary prediction. Also, the subsequent prediction and preliminary prediction provide predictions of the same type of processing behaviour (e.g. both providing prediction of branch direction outcome, or both providing prediction of branch target address, in the case of the prediction circuitry being a branch predictor 40 as in FIG. 1). As mentioned above, it will be appreciated that the subsequent prediction need not be based on all of the prediction state data and may only be based on more of the prediction state data than the preliminary prediction.

At step 53, it is determined whether the subsequent prediction is different to the preliminary prediction, i.e. has a prediction divergence occurred? If the predictions are the same, then no further action is needed, as the other component has already been provided with the preliminary prediction, and the process returns to step 50 to generate the next prediction. If a prediction divergence has occurred, then at step 54, the subsequent prediction overrides the preliminary prediction, such that the at least one other component is caused to use the subsequent prediction instead of the preliminary prediction.

At step 55, it is determined whether the divergence-triggered update condition has been satisfied. This condition is dependent on at least the occurrence of a prediction divergence as identified at step 53, but may also in some examples be further dependent on other conditions. If the divergence-triggered update condition is not satisfied, then no further action is needed, and the process returns to step 50 to generate the next prediction. If the divergence-triggered update condition is satisfied, then at step 56, the divergence-triggered update is applied to the subset 42-2 of the prediction state data used for the preliminary prediction.

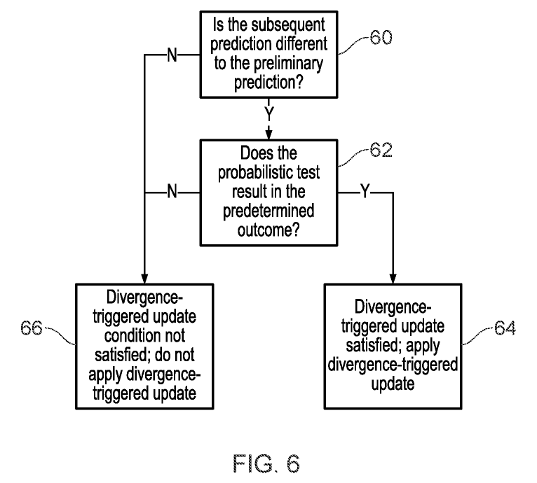

Whether or not the divergence-triggered update condition is satisfied depends on any number of conditions, including at least the occurrence of a prediction divergence as detected at step 53. In some examples, it may be undesirable to apply the divergence-triggered update on every occurrence of a prediction divergence because to do so may negatively affect the accuracy of the prediction state data. Accordingly, in such examples, the divergence-triggered update condition could be further dependent on a predetermined outcome resulting from a probabilistic test. FIG. 6 illustrates a method that may be included as a sub-process of step 55 in FIG. 5. In step 60, it is determined whether the subsequent prediction is different to the preliminary prediction (i.e. whether a prediction divergence has occurred). If so, then at step 62 it is checked whether a probabilistic test results in the predetermined outcome. The probabilistic test may vary based on the implementation, and any test that has a given probability to provide the predetermined outcome will be suitable for the present technique. The probability can be fixed or configurable, and may often be a relatively low probability, so that it is more probable that the probabilistic test does not provide the predetermined outcome than that the probabilistic test provides the predetermined outcome.If the predetermined test provides the predetermined outcome, then the divergence-triggered update is satisfied at step 64. Therefore, the divergence-triggered update can be applied.

If the result of steps 60 or 62 is in the negative, then the divergence-triggered update condition is not satisfied at step 66. Therefore, the divergence-triggered update is not applied. It will be appreciated that steps 60 and 62 do not have to occur in the illustrated order and may be performed the other way around or in parallel.

Returning to the example of FIG. 4, the state update circuitry 46 optionally comprises a test counter 48 for use in performing the probabilistic test according to some examples. The value of the test counter 48 is incremented each time a prediction is made (or each time a prediction divergence occurs) and the probabilistic test is determined to give the predetermined outcome when, on a given instance of carrying out the probabilistic test in response to prediction divergence being detected), the test counter 48 is determined to have a predetermined value (the test could be carried out either before or after the update to the test counter 48 triggered by the prediction which encountered the prediction divergence). For example, for a given probability of 25%, then a test counter 48 incrementing from 0 to 3 (and then cycling back to 0 on further increments) can be provided where a value of, say, 3 (or any other arbitrarily chosen value) is the predetermined value.

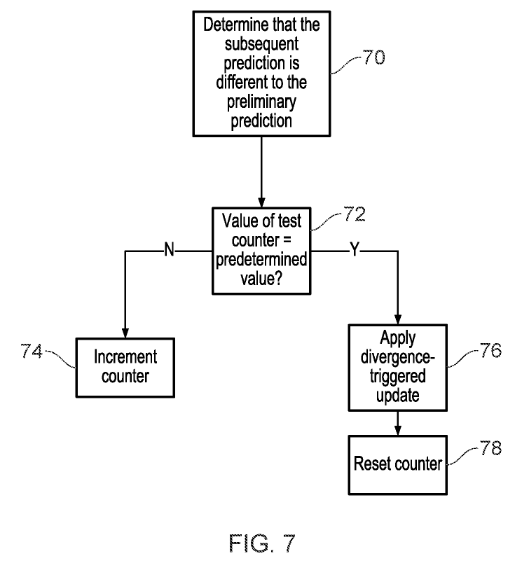

FIG. 7 illustrates a method of controlling the test counter 48 to perform the probabilistic test. At step 70, it is determined that the subsequent prediction is different to the preliminary prediction (e.g. yes at step 60 in FIG. 6). At step 72, it is checked whether the value of the test counter 48 is the predetermined value. If not, then the test counter 48 is incremented at step 74. If the test counter 48 does have the predetermined value, then the probabilistic test is deemed to have resulting in the predetermined result and the divergence-triggered update can be applied at step 76. At step 78, the test counter 48 can be reset. In some examples, where the predetermined value is the highest number that can be counted by the test counter 48, the test counter 48 can be reset by incrementing again to overflow the test counter 48 back to zero.

In the example of FIG. 4, a single global test counter 48 is shared between all entries of the prediction tables (e.g. TAGE tables shown in FIG. 3), so regardless of which prediction state entry is used to form the preliminary/subsequent predictions, the probabilistic test is evaluated based on the same test counter 48. However, other examples may provide local test counters 48 specific to particular TAGE tables or to particular subsets of prediction state entries in the tables, so that the particular test counter that is incremented at step 74 or used to conduct the test at step 72 of FIG. 7 may depend on which address is input for prediction.

Also, it will be appreciated that use of such a test counter 48 is just one way of implementing a probabilistic test, and other examples may use other techniques to filter whether the divergence-triggered update is applied so that the update is applied only on a certain fraction of times the prediction divergence is encountered. For example, a random or pseudorandom number generator may provide a random/pseudorandom value which may be compared with a given value and the probabilistic test may be determined to be satisfied if the random/pseudorandom value equals the given value. Also, it may be possible to sample an arbitrary set of bits (or signals on buses) gathered from one or more other components of the processing apparatus 2, where those bits may not necessarily be related to the prediction performed by the branch predictor 40. If the bits are chosen appropriately, such that the probability of those bits/signals taking a given value may be expected to have a relatively uniform distribution for each possible value of those bits/signals, then the sampled bits/signals could act as a number which can be compared with a given target value to determine whether the predetermined outcome of the probabilistic test has been satisfied.

Hence, it will be appreciated that the probabilistic test is not limited to the test counter embodiment shown in FIG. 4.

By use of the above techniques, and in particular by applying a divergence-triggered update when the divergence-triggered update condition is satisfied, the occurrence of pipeline bubbles can be reduced, while maintaining accurate prediction state data. Hence, the performance of the pipeline 4 and power efficiency of the predictor 40 can be improved thus resulting in improved performance of the data processing apparatus 2 as a whole.

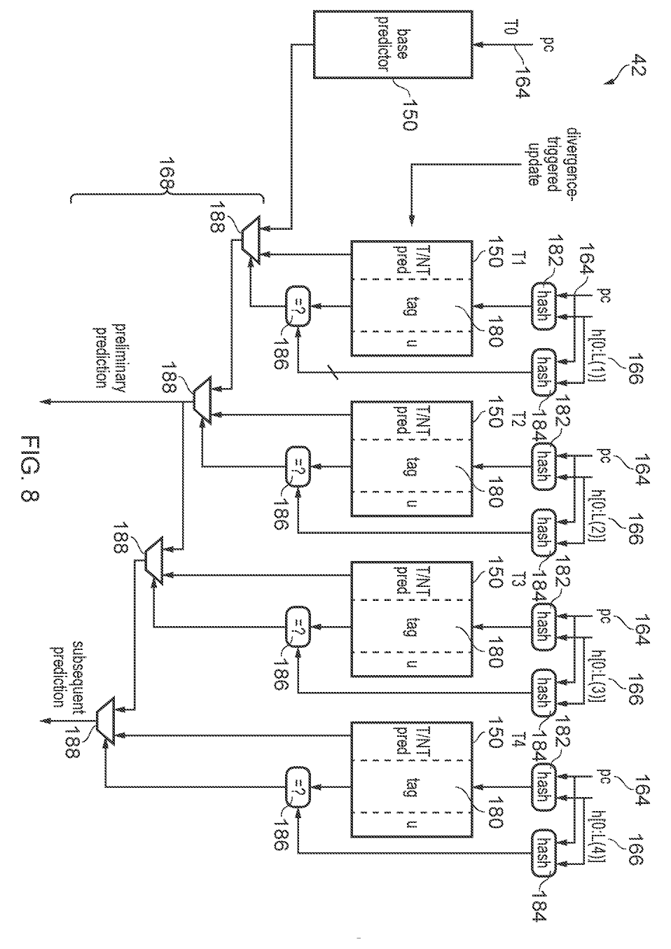

As mentioned above, the present techniques may be applied to a predictor, regardless of what is being predicted (e.g. branch directions, branch targets or data values). The present techniques can also be applied to various different configurations of predictor. FIG. 8 shows a specific example of a branch predictor 40, which is a TAGE (tagged-geometric) predictor for providing branch direction predictions (taken/not-taken). In the TAGE branch direction predictor, the prediction state data 42 comprises branch prediction tables 150 including a base prediction table T0 and a number of tagged-geometric (TAGE) tables T1 to T4. While this example shows four TAGE tables for conciseness, it will be appreciated that TAGE predictors could be provided with a larger number of tables if desired, e.g. 8 or 16. The base predictor T0 is looked up based on the program counter PC alone, while the TAGE tables T1 to T4 are looked up based the PC 164 and successively increasing lengths of history information 166, so that T1 uses a shorter sequence of history information compared to T2, T2 uses a shorter sequence of history information compared to T3, and so on. In this example T4 is the table which uses the longest sequence of history information. Each prediction entry specifies a prediction counter (“pred”), for example a 2-bit counter which provides a bimodal indication of whether the prediction is to be taken or not taken (e.g. counter values 11, 10, 00, 01 may respectively indicate predictions of: strongly predicted taken, weakly predicted taken, weakly predicted not taken, and strongly predicted not taken). Each entry also specifies a tag value 180 which is compared with a tag hash generated from the program counter 164 and history information 166 to detect whether the entry corresponds to the current block being looked up (the tag distinguishes between multiple blocks whose index hash values alias onto the same entry of the table). The lookup circuitry includes index hashing circuitry 182 for generating an index hash used to select one or more selected entries of the table, tag hashing circuitry 184 for generating a tag hash value to be written to a newly allocated entry or for comparing with an existing entry’s tag value 180 on a lookup, and comparison circuitry 186 for comparing the tag value 180 read out from one or more looked up entries with the calculated tag hash generated by the tag hashing circuitry 184 to determine whether a hit has been detected. Each prediction entry of the branch predictor 42 may also have a usefulness value (u) used for controlling replacement of prediction entries (e.g. the usefulness value of a given entry may be reset to an initial value when a hit is detected against that entry or when the entry is first allocated, and the usefulness values of all entries in a given table may be incremented in response to a miss in that table or on an allocation of a new entry, so that over time the usefulness values may distinguish more frequently used entries from less frequently used entries).

For a TAGE predictor, TAGE prediction generating circuitry 168 comprises a cascaded sequence of selection multiplexers 188 which select between the alternative predictions returned by any of the prediction tables 150 which generate a hit. The base predictor 150 may be used as a fall-back predictor in case none of the other TAGE tables generate a hit (a hit occurs when the tag in the looked up entry matches the tag hash generated based on the indexing information). In a pipelined predictor arrangement, the prediction generating circuitry 168 generates two or more predictions depending on the predictions returned by different numbers of tables. In the example of FIG. 8, the prediction generating circuitry 168 generates a preliminary prediction based on the base predictor T0 and the T1 and T2 prediction tables 150. The prediction generating circuitry 168 then generates a subsequent prediction based on the base predictor 150 and all of the prediction tables 150. It will be appreciated that while FIG. 8 shows two pipelined predictions (the preliminary prediction and subsequent prediction), some TAGE predictors may have greater numbers of TAGE tables and so may provide three or more predictions in different pipeline stages, based on subsets of prediction state of successively greater size.

The cascaded multiplexers 188 are such that if the table T4 indexed with the longest sequence of history generates a hit then its prediction will be output as the prediction result for the subsequent prediction, but if it misses then if the preceding table T3 generates a hit then the T3 prediction will be output as the prediction result for the subsequent prediction, and so on, so that the prediction which gets selected as the subsequent prediction is the prediction output by the table (among those tables which generated a hit) which corresponds to the longest sequence of history considered in the indexing. That is, any tables which miss are excluded from the selection, and among the remaining tables the one with the longest sequence of history in its indexing information is selected, and if none of the TAGE tables T1 to T4 generate a hit then the base predictor T0 is selected.

This approach is extremely useful for providing high performance because a single table indexed with a fixed length of branch history has to trade off the accuracy of predictions against the likelihood of lookups hitting in the table. A table indexed with a relatively short sequence of branch history may be more likely to generate a hit, because it is more likely that the recently seen history leading to the current block is the same as a previously seen sequence of history for which an entry is recorded in the table, but as the shorter sequence of history cannot distinguish as precisely between the different routes by which the program flow may have reached the current block, it is more likely that the prediction indicated in the hit entry may be incorrect. On the other hand, for the table T4 which is indexed based on the longest sequence of history, this can be extremely useful for predicting harder to predict branches which need to delve further into the past in terms of exploring the history so that that the pattern of program execution which led to that branch can be characterised and an accurate prediction made, however, it is less likely on subsequent occasions that the longer sequence of history will exactly match the sequence of history leading up to the current block and so the hit rate is lower in a table indexed based on a longer sequence of history. Accordingly, a hit in the table T4 would be expected to produce a more accurate prediction result, such that the subsequent prediction is more accurate than the preliminary prediction, which at most is based on a hit in the table T2. By providing a range of tables with different lengths of history used for indexing, this can balance these factors so that while the hardest to predict branches which would be difficult to predict using other branch predictors can be successfully predicted with the longer table T4, other easier to predict branches which do not require the full prediction capability of T4 can be predicted using one of the earlier tables indexed based on shorter history so that it is more likely that a hit will be detected on a prediction lookup, thus increasing the percentage of branches for which a successful prediction can be made and therefore improving prediction accuracy and performance. Hence, TAGE predictors are one of the most accurate predictors known.

On the other hand, the preliminary prediction applies the same TAGE prediction prioritisation principles, but based solely on a reduced subset of tables, in this example based on the base table T0 and tables T1, T2. Hence, even if there would have been a hit in table T3 or T4, the preliminary prediction is nevertheless based on the longest history table that generated a hit in the lookup.

In accordance with the present techniques, when the subsequent prediction is determined to be different to the preliminary prediction, a divergence-triggered update may be applied as described above. In the specific example of the TAGE predictor in FIG. 8, the preliminary prediction is based on the base predictor T0 and the T1 and T2 prediction tables 150 (i.e. corresponding to the subset of the prediction state data). Therefore, the divergence-triggered update would be applied to one of the base predictor T0 or the T1 or T2 prediction tables 150. Applying an update in this way is counter-intuitive for a TAGE algorithm, which typically only updates the table entry that is used as the final prediction result in response to an actual outcome being different (e.g. a misprediction-triggered update). Therefore, the present techniques provide a separate update which is applied to an entry that is not used as the final prediction (i.e. because the preliminary prediction was overridden) in response to the prediction divergence. The functionality of the misprediction-triggered update may be unaffected by the present techniques, and indeed both a misprediction-triggered update and the divergence-triggered update may be performed if the conditions for both are satisfied.

While FIG. 8 shows a TAGE predictor for branch direction prediction (providing a taken/not-taken prediction), a similar TAGE predictor could also be provided for prediction of branch target address, and the divergence-triggered updates may also be applied for such a TAGE-based branch target address predictor.

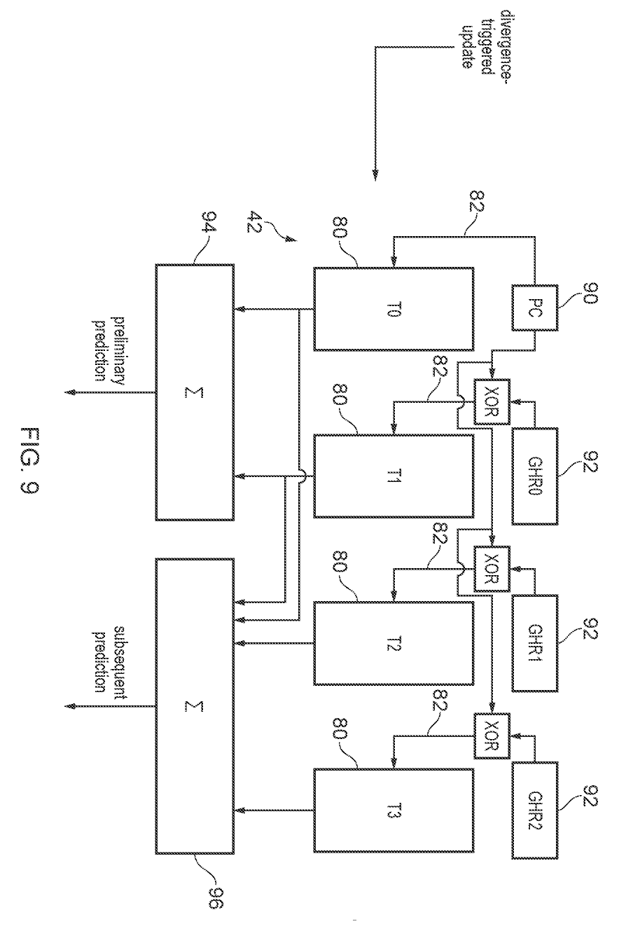

It will be appreciated that a TAGE predictor is just one example. FIG. 9 illustrates another specific example, where the branch predictor 40 is a perceptron predictor. In a perceptron predictor, the prediction state data 42 comprises a plurality of tables 80 indexed based on an index 82 constructed from a program counter value or a combination of the program counter value 90 and a global history information from respective global history registers 92. Unlike the TAGE predictor, for the perceptron predictor each prediction entry provides a weight value, and the weights read from the looked up entries in each of the tables 80 are added together. Also, for the perceptron predictor, the entries of tables 80 are not tagged, so there is no concept of a hit/miss in these tables.

In a pipelined arrangement, a preliminary prediction can be generated based on the weights from only a subset of the tables 80. In the example of FIG. 9, the preliminary prediction generating circuitry 94 uses the weights from the T0 and T1 tables 80 and adds them together to produce a sum value indicative of a predicted outcome. The subsequent prediction generating circuitry 96 uses the weights from all of the T0 to T3 tables 80 and adds them together to produce a sum value indicative of another predicted outcome. Hence, rather than making a cascaded selection between the alternative predictions provided by each table, the perceptron adds the weights from each of the tables together and then the total of all of the weights indicates the predicted behaviour, e.g. whether the branch outcome prediction is taken or not taken (for example, the sum produced by the weight addition function may be compared with a threshold and the predicted behaviour may have one outcome (e.g. taken) if the sum exceeds the threshold and another outcome (e.g. not taken) if the sum does not exceed the threshold).

In accordance with the present techniques, when the subsequent prediction is determined to be different to the preliminary prediction, a divergence-triggered update may be applied as described above. In the specific example of the perceptron predictor as described above, the preliminary prediction is only based on the T0 and T1 tables 80 (corresponding to the subset of prediction state data). Therefore, the divergence-triggered update would be applied to the T0 or T1 tables 80. In some examples of the perceptron, the weights may be updated based on a predefined weight update function which controls how and to what extent the value of an updated weight is changed. For the divergence-triggered update, the weight update function may cover tables T0 and T1 used as the subset of prediction state used for the preliminary prediction (but does not cover any updates to the remaining subset of prediction state T2, T3 which is used for the subsequent prediction but not used for the preliminary prediction). In contrast, misprediction-triggered updates caused by the subsequent prediction being determined to be incorrect may apply a weight update function that is applied to entries in the wider set of tables T0-T3 used for the subsequent prediction.

The moment at which a divergence-triggered update is applied may vary in different implementations. For example, different implementations may apply the divergence-triggered update when the subsequent prediction is generated and the prediction divergence is detected (i.e. at “prediction time”), or when the actual outcome has been determined such as when an instruction is executed (i.e. at “execute time”).

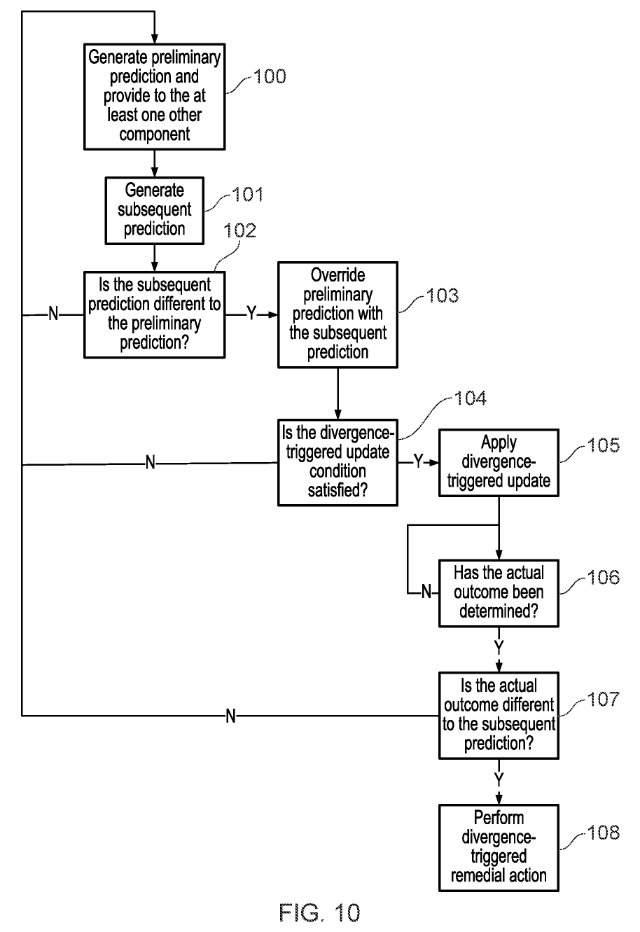

FIG. 10 illustrates a method for when the divergence-triggered update is applied at prediction time, before the actual outcome is known. At step 100, the preliminary prediction is generated followed by step 101, where the subsequent prediction is generated. At step 102, it is determined whether the subsequent prediction is different to the preliminary prediction. If not, then there is no prediction divergence and the process returns to step 100 to generate the next prediction. If a prediction divergence occurs, the preliminary prediction is overridden by the subsequent prediction at step 103, as described in previous examples. At step 104, it is determined whether the divergence-triggered update condition is satisfied. Step 104 may be similar to as described in previous examples such as including checking a result of a probabilistic test. If the divergence-triggered update condition is not satisfied, then the divergence-triggered update is not applied and the process returns to step 100.

If the divergence-triggered update condition is satisfied, then the divergence-triggered update is applied at step 105. In this example, the actual outcome has not yet been determined, and hence it is not yet known whether the subsequent prediction is correct. It would be appreciated that, if the subsequent prediction is incorrect, then updating the subset of prediction state data to correspond to the subsequent prediction may not be advantageous. Accordingly, once the actual outcome has been determined at step 106, for example by the execute stage 16 of FIG. 1 executing a branch instruction or a load instruction, it can then be determined whether the actual outcome is different to the subsequent prediction at step 107. If not, then the subsequent prediction was correct and no further action is required. However, if the actual outcome is different to the subsequent prediction, then the subsequent prediction is incorrect and a divergence-triggered remedial action can be performed at step 108.

The divergence-triggered remedial action is directed towards correcting the prediction state data. In some examples, the prediction state data may be reverted to a state prior to the application of the divergence-triggered update, such that the update is undone. In other examples, an additional update may be performed to so that the subset of the prediction state data reflects the incorrect prediction in a similar way to a misprediction-triggered update. In still other examples, the potential inaccuracy caused by the divergence-triggered update may be sufficiently small, such that the prediction state data is left to correct itself over time as further predictions are made and misprediction-triggered updates are applied (so in some cases steps 107 and 108 are not necessary).

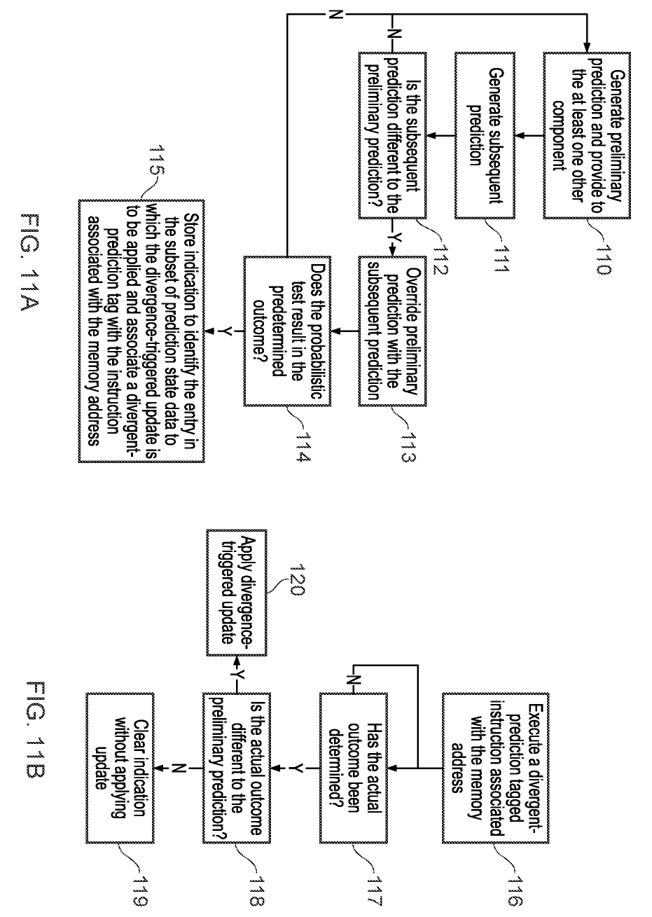

FIGS. 11A and 11B illustrates a method where the divergence-triggered update is applied at execution time, once the actual outcome is known. In this example, the divergence-triggered update condition being satisfied is further dependent on the actual outcome being different to the preliminary prediction. Hence if the preliminary prediction had actually been correct, despite being overridden by the subsequent prediction, a divergence-triggered update would not be applied, thus preventing the subset of the prediction state data from producing incorrect preliminary predictions in the future.

FIG. 11A illustrates a part of the process which occurs at prediction time. As in previous examples, the preliminary prediction and subsequent prediction are generated in steps 110 and 111, and then it is determined whether the subsequent prediction is different to the preliminary prediction in step 112. When a prediction divergence is detected, the preliminary prediction is overridden with the subsequent prediction at step 113. In this example, the divergence-triggered update condition is dependent on the actual outcome, so it is not yet known whether the divergence-triggered update condition is satisfied or not. Nonetheless, at step 114 any other conditions may still be evaluated, such as determining the result of the probabilistic test as described in previous examples. If the divergence-triggered update condition is otherwise satisfied subject to the determination of the actual outcome, then an indication to identify an entry in the subset of prediction state data is stored at step 115. This indication can be used by the state update circuitry 46 (later on, at execute time) to apply the divergence-triggered update to the correct entry. Also in step 115, a divergence-triggered tag is associated with the instruction associated with the memory address for which a prediction is being made. For example, where the prediction is a branch direction prediction, the divergence-triggered tag is associated with the corresponding branch instruction. The tag can pass down the pipeline with that instruction, to signal to the execute stage 16 that is resolving the actual outcome whether previously a prediction divergence between the preliminary and subsequent predictions was identified at prediction time by the prediction circuitry 40.

As the instruction proceeds along a processing pipeline such as the pipeline 4 shown in FIG. 1, it eventually reaches the execute stage 16 at the execution time. FIG. 11B illustrates a part of the process which occurs at execution time. At step 116, the instruction that had been associated with a divergent-prediction tag at prediction time is executed and the actual outcome is determined at step 117. At step 118, it is then determined whether the actual outcome is different to the preliminary prediction such that it can be determined whether the divergence-triggered update condition is satisfied. If the actual outcome is the same as the preliminary prediction, then it would not be advantageous to update the prediction state data to reflect an incorrect prediction (i.e. the subsequent prediction). Therefore, the divergence-triggered update is not applied. Instead, the indication is simply cleared at step 119. If the divergence-triggered update is different to the preliminary prediction, then the divergence-triggered update is applied at step 120.

In a case where the prediction is of one of two possibilities (e.g. a branch being taken or not taken), then one of the preliminary prediction or subsequent prediction would be correct in a prediction divergence. In such cases, the state update circuitry 46 would apply a misprediction-triggered update or divergence-triggered update respectively. In another case where the prediction is of one of many possibilities (e.g. the target address of a branch instruction), then it is possible for both predictions to be incorrect. In such cases, the state update circuitry 46 may apply both a misprediction-triggered update and a divergence-triggered update.

Concepts described herein may be embodied in a system comprising at least one packaged chip. The apparatus described earlier is implemented in the at least one packaged chip (either being implemented in one specific chip of the system, or distributed over more than one packaged chip). The at least one packaged chip is assembled on a board with at least one system component. A chip-containing product may comprise the system assembled on a further board with at least one other product component. The system or the chip-containing product may be assembled into a housing or onto a structural support (such as a frame or blade).

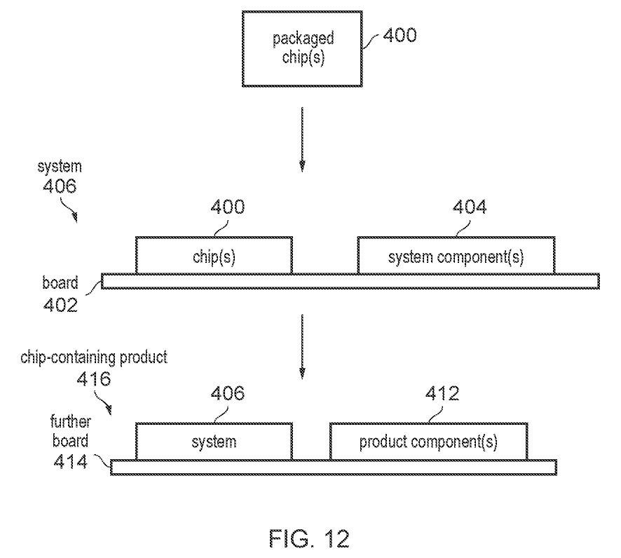

As shown in FIG. 12, one or more packaged chips 400, with the apparatus described above implemented on one chip or distributed over two or more of the chips, are manufactured by a semiconductor chip manufacturer. In some examples, the chip product 400 made by the semiconductor chip manufacturer may be provided as a semiconductor package which comprises a protective casing (e.g. made of metal, plastic, glass or ceramic) containing the semiconductor devices implementing the apparatus described above and connectors, such as lands, balls or pins, for connecting the semiconductor devices to an external environment. Where more than one chip 400 is provided, these could be provided as separate integrated circuits (provided as separate packages), or could be packaged by the semiconductor provider into a multi-chip semiconductor package (e.g. using an interposer, or by using three-dimensional integration to provide a multi-layer chip product comprising two or more vertically stacked integrated circuit layers).

In some examples, a collection of chiplets (i.e. small modular chips with particular functionality) may itself be referred to as a chip. A chiplet may be packaged individually in a semiconductor package and/or together with other chiplets into a multi-chiplet semiconductor package (e.g. using an interposer, or by using three-dimensional integration to provide a multi-layer chiplet product comprising two or more vertically stacked integrated circuit layers).

The one or more packaged chips 400 are assembled on a board 402 together with at least one system component 404 to provide a system 406. For example, the board may comprise a printed circuit board. The board substrate may be made of any of a variety of materials, e.g. plastic, glass, ceramic, or a flexible substrate material such as paper, plastic or textile material. The at least one system component 404 comprise one or more external components which are not part of the one or more packaged chip(s) 400. For example, the at least one system component 404 could include, for example, any one or more of the following: another packaged chip (e.g. provided by a different manufacturer or produced on a different process node), an interface module, a resistor, a capacitor, an inductor, a transformer, a diode, a transistor and/or a sensor.

A chip-containing product 416 is manufactured comprising the system 406 (including the board 402, the one or more chips 400 and the at least one system component 404) and one or more product components 412. The product components 412 comprise one or more further components which are not part of the system 406. As a non-exhaustive list of examples, the one or more product components 412 could include a user input/output device such as a keypad, touch screen, microphone, loudspeaker, display screen, haptic device, etc.; a wireless communication transmitter/receiver; a sensor; an actuator for actuating mechanical motion; a thermal control device; a further packaged chip; an interface module; a resistor; a capacitor; an inductor; a transformer; a diode; and/or a transistor. The system 406 and one or more product components 412 may be assembled on to a further board 414.

The board 402 or the further board 414 may be provided on or within a device housing or other structural support (e.g. a frame or blade) to provide a product which can be handled by a user and/or is intended for operational use by a person or company.

The system 406 or the chip-containing product 416 may be at least one of: an end-user product, a machine, a medical device, a computing or telecommunications infrastructure product, or an automation control system. For example, as a non-exhaustive list of examples, the chip-containing product could be any of the following: a telecommunications device, a mobile phone, a tablet, a laptop, a computer, a server (e.g. a rack server or blade server), an infrastructure device, networking equipment, a vehicle or other automotive product, industrial machinery, consumer device, smart card, credit card, smart glasses, avionics device, robotics device, camera, television, smart television, DVD players, set top box, wearable device, domestic appliance, smart meter, medical device, heating/lighting control device, sensor, and/or a control system for controlling public infrastructure equipment such as smart motorway or traffic lights.

Concepts described herein may be embodied in computer-readable code for fabrication of an apparatus that embodies the described concepts. For example, the computer-readable code can be used at one or more stages of a semiconductor design and fabrication process, including an electronic design automation (EDA) stage, to fabricate an integrated circuit comprising the apparatus embodying the concepts. The above computer-readable code may additionally or alternatively enable the definition, modelling, simulation, verification and/or testing of an apparatus embodying the concepts described herein.

For example, the computer-readable code for fabrication of an apparatus embodying the concepts described herein can be embodied in code defining a hardware description language (HDL) representation of the concepts. For example, the code may define a register-transfer-level (RTL) abstraction of one or more logic circuits for defining an apparatus embodying the concepts. The code may define a HDL representation of the one or more logic circuits embodying the apparatus in Verilog, SystemVerilog, Chisel, or VHDL (Very High-Speed Integrated Circuit Hardware Description Language) as well as intermediate representations such as FIRRTL. Computer-readable code may provide definitions embodying the concept using system-level modelling languages such as SystemC and SystemVerilog or other behavioural representations of the concepts that can be interpreted by a computer to enable simulation, functional and/or formal verification, and testing of the concepts.

Additionally or alternatively, the computer-readable code may define a low-level description of integrated circuit components that embody concepts described herein, such as one or more netlists or integrated circuit layout definitions, including representations such as GDSII. The one or more netlists or other computer-readable representation of integrated circuit components may be generated by applying one or more logic synthesis processes to an RTL representation to generate definitions for use in fabrication of an apparatus embodying the invention. Alternatively or additionally, the one or more logic synthesis processes can generate from the computer-readable code a bitstream to be loaded into a field programmable gate array (FPGA) to configure the FPGA to embody the described concepts. The FPGA may be deployed for the purposes of verification and test of the concepts prior to fabrication in an integrated circuit or the FPGA may be deployed in a product directly.

The computer-readable code may comprise a mix of code representations for fabrication of an apparatus, for example including a mix of one or more of an RTL representation, a netlist representation, or another computer-readable definition to be used in a semiconductor design and fabrication process to fabricate an apparatus embodying the invention. Alternatively or additionally, the concept may be defined in a combination of a computer-readable definition to be used in a semiconductor design and fabrication process to fabricate an apparatus and computer-readable code defining instructions which are to be executed by the defined apparatus once fabricated.

Such computer-readable code can be disposed in any known transitory computer-readable medium (such as wired or wireless transmission of code over a network) or non-transitory computer-readable medium such as semiconductor, magnetic disk, or optical disc. An integrated circuit fabricated using the computer-readable code may comprise components such as one or more of a central processing unit, graphics processing unit, neural processing unit, digital signal processor or other components that individually or collectively embody the concept.

Some examples are set out in the following clauses:

(1) An apparatus comprising: prediction state storage circuitry to maintain a set of prediction state data; prediction circuitry configured to: in a preliminary pipeline stage, generate a preliminary prediction associated with a given memory address in dependence on a subset of the prediction state data and to provide the preliminary prediction for use by at least one other component, and in a subsequent pipeline stage, generate a subsequent prediction associated with the given memory address in dependence on the set of the prediction state data; overriding circuitry responsive to a determination that the subsequent prediction is different from the preliminary prediction to cause the at least one other component to use the subsequent prediction instead of the preliminary prediction; and state update circuitry configured to apply, in response to detecting a divergence-triggered update condition being satisfied, a divergence-triggered update to the subset of the prediction state data used to generate the preliminary prediction, wherein the divergence-triggered update condition being satisfied is dependent on the subsequent prediction being different from the preliminary prediction.

(2) The apparatus of clause (1), wherein the divergence-triggered update condition being satisfied is further dependent on a predetermined outcome resulting from a probabilistic test having a given probability of providing the predetermined outcome.

(3) The apparatus of clause (2), wherein the state update circuitry comprises a test counter, and the probabilistic test comprises determining whether the test counter has a predetermined value.

(4) The apparatus of clause (3), wherein state update circuitry is configured to increment the test counter in response to the determination that the subsequent prediction is different from the preliminary prediction.

(5) The apparatus of any of clauses (2) to (4), wherein the given probability of the probabilistic test resulting in the predetermined outcome is fixed.

(6) The apparatus of any of clauses (2) to (4), wherein the given probability of the probabilistic test resulting in the predetermined outcome is dynamically adjustable.

(7) The apparatus of clause (6), wherein the given probability is dynamically adjustable depending on a rate of updates to the prediction state data triggered based on detection that the subsequent prediction is incorrect.

(8) The apparatus of any preceding clause, wherein the prediction circuitry is configured to generate the subsequent prediction in dependence on the subset of the prediction state data and on at least some of the set of prediction state data that is not in the subset.

(9) The apparatus of any preceding clause, wherein the state update circuitry is configured to continue to apply the divergence-triggered update when the divergence-triggered update condition is satisfied, even when the subsequent prediction is determined to be correct.

(10) The apparatus of any preceding clause, wherein the prediction circuitry comprises a tagged geometric length predictor and the set of prediction state data comprises one or more short-history prediction tables associated with a shorter history length and one or more long-history prediction tables associated with a longer history length; the prediction circuitry is configured to generate the preliminary prediction in dependence on a hit on a preliminary entry in the one or more short-history prediction tables; and the prediction circuitry is configured to generate the subsequent prediction in dependence on a hit on a subsequent entry in the one or more short-history predictions tables or the one or more long-history prediction tables.

(11) The apparatus of clause (10), wherein the prediction circuitry is configured to prioritise a hit in the one or more long-history prediction tables over a hit in the one or more short-history prediction table for generating the subsequent prediction.

(12) The apparatus of clause (10) or clause (11), wherein the state update circuitry is configured to apply the divergence-triggered update to the preliminary entry in the one or more short-history prediction tables.

(13) The apparatus of any of clauses (10) to (12), wherein in response to determining an indication that the subsequent prediction is incorrect and that the divergence-triggered update condition is also satisfied, the state update circuitry is configured to apply both of: the divergence-triggered update to the preliminary entry, and a further misprediction-triggered update to the subsequent entry.

(14) The apparatus of any of clauses (1) to (9), wherein the prediction circuitry comprises a perceptron predictor and the set of prediction state data comprises a plurality of weights; the prediction circuitry is configured to generate the preliminary prediction by computing a prediction value based on a subset of the plurality of weights; and the prediction circuitry is configured to generate the subsequent prediction by computing a prediction value based on the plurality of weights.

(15) The apparatus of clause (14), wherein the state update circuitry is configured to apply the divergence-triggered update according to a weight update function applied to the subset of the plurality of weights used to generate the preliminary prediction.

(16) The apparatus of any preceding clause, wherein the state update circuitry is configured to apply the divergence-triggered update before an actual outcome associated with the given memory address has been determined.

(17) The apparatus of any of clause (1) to (15), wherein the state update circuitry is configured to apply the divergence-triggered update after a determination of an actual outcome associated with the given memory address.

(18) The apparatus of clause (17), wherein the divergence-triggered update condition being satisfied is further dependent on the preliminary prediction being different to the actual outcome.

(19) The apparatus of clause (17) or clause (18), wherein the state update circuitry is configured to store an indication identifying an entry in the subset of prediction state data to which the divergence-triggered update is to be applied.

(20) The apparatus of any of clauses (17) to (19), wherein the overriding circuitry is configured to associate a divergent-prediction tag with a given instruction associated with the given memory address in response to the determination that the subsequent prediction is different from the preliminary prediction; and the state update circuitry is configured to apply the divergence-triggered update after the actual outcome is determined for an instruction associated with the divergent-prediction tag by the overriding circuitry.

(21) The apparatus of any of clauses (17) to (20), wherein the divergence-triggered update is based on the actual outcome associated with the given memory address.

(22) The apparatus of any preceding clause, wherein the preliminary prediction and the subsequent prediction predict one of: a branch outcome direction; a branch outcome target address; a data value.

(23) A system comprising: the apparatus of any preceding clause, implemented in at least one packaged chip; at least one system component; and a board; wherein the at least one packaged chip and the at least one system component are assembled on the board.

(24) A chip-containing product comprising the system of clause (23), wherein the system is assembled on a further board with at least one other product component.

(25) A method comprising: maintaining a set of prediction state data; generating, in a preliminary pipeline stage, a preliminary prediction associated with a given memory address in dependence on a subset of the prediction state data and to provide the preliminary prediction for use by at least one other component, and generating, in a subsequent pipeline stage, a subsequent prediction associated with the given memory address in dependence on the set of the prediction state data; causing, in response to a determination that the subsequent prediction is different from the preliminary prediction, the at least one other component to use the subsequent prediction instead of the preliminary prediction; and applying, in response to detecting a divergence-triggered update condition being satisfied, a divergence-triggered update to the subset of the prediction state data used to generate the preliminary prediction, wherein the divergence-triggered update condition being satisfied is dependent on the subsequent prediction being different from the preliminary prediction.

(26) A non-transitory computer-readable medium storing computer-readable code for fabrication of an apparatus comprising: prediction state storage circuitry to maintain a set of prediction state data; prediction circuitry configured to: in a preliminary pipeline stage, generate a preliminary prediction associated with a given memory address in dependence on a subset of the prediction state data and to provide the preliminary prediction for use by at least one other component, and in a subsequent pipeline stage, generate a subsequent prediction associated with the given memory address in dependence on the set of the prediction state data; overriding circuitry responsive to a determination that the subsequent prediction is different from the preliminary prediction to cause the at least one other component to use the subsequent prediction instead of the preliminary prediction; and state update circuitry configured to apply, in response to detecting a divergence-triggered update condition being satisfied, a divergence-triggered update to the subset of the prediction state data used to generate the preliminary prediction, wherein the divergence-triggered update condition being satisfied is dependent on the subsequent prediction being different from the preliminary prediction.

In the present application, the words “configured to…” are used to mean that an element of an apparatus has a configuration able to carry out the defined operation. In this context, a “configuration” means an arrangement or manner of interconnection of hardware or software. For example, the apparatus may have dedicated hardware which provides the defined operation, or a processor or other processing device may be programmed to perform the function. “Configured to” does not imply that the apparatus element needs to be changed in any way in order to provide the defined operation.

Although illustrative embodiments of the invention have been described in detail herein with reference to the accompanying drawings, it is to be understood that the invention is not limited to those precise embodiments, and that various changes and modifications can be effected therein by one skilled in the art without departing from the scope of the invention as defined by the appended claims.

1. An apparatus comprising:
prediction state storage circuitry to maintain a set of prediction state data;
prediction circuitry configured to:
in a preliminary pipeline stage, generate a preliminary prediction associated with a given memory address in dependence on a subset of the prediction state data and to provide the preliminary prediction for use by at least one other component, and
in a subsequent pipeline stage, generate a subsequent prediction associated with the given memory address in dependence on the set of the prediction state data;
overriding circuitry responsive to a determination that the subsequent prediction is different from the preliminary prediction to cause the at least one other component to use the subsequent prediction instead of the preliminary prediction; and
state update circuitry configured to apply, in response to detecting a divergence-triggered update condition being satisfied, a divergence-triggered update to the subset of the prediction state data used to generate the preliminary prediction, wherein the divergence-triggered update condition being satisfied is dependent on the subsequent prediction being different from the preliminary prediction.

2. The apparatus of claim 1, wherein the divergence-triggered update condition being satisfied is further dependent on a predetermined outcome resulting from a probabilistic test having a given probability of providing the predetermined outcome.

3. The apparatus of claim 2, wherein the state update circuitry comprises a test counter, and the probabilistic test comprises determining whether the test counter has a predetermined value.

4. The apparatus of claim 3, wherein state update circuitry is configured to increment the test counter in response to the determination that the subsequent prediction is different from the preliminary prediction.

5. The apparatus of claim 2, wherein the given probability of the probabilistic test resulting in the predetermined outcome is dynamically adjustable.

6. The apparatus of claim 5, wherein the given probability is dynamically adjustable depending on a rate of updates to the prediction state data triggered based on detection that the subsequent prediction is incorrect.

7. The apparatus of claim 1, wherein the prediction circuitry is configured to generate the subsequent prediction in dependence on the subset of the prediction state data and on at least some of the set of prediction state data that is not in the subset.

8. The apparatus of claim 1, wherein the state update circuitry is configured to continue to apply the divergence-triggered update when the divergence-triggered update condition is satisfied, even when the subsequent prediction is determined to be correct.

9. The apparatus of claim 1, wherein
the prediction circuitry comprises a tagged geometric length predictor and the set of prediction state data comprises one or more short-history prediction tables associated with a shorter history length and one or more long-history prediction tables associated with a longer history length;
the prediction circuitry is configured to generate the preliminary prediction in dependence on a hit on a preliminary entry in the one or more short-history prediction tables; and
the prediction circuitry is configured to generate the subsequent prediction in dependence on a hit on a subsequent entry in the one or more short-history predictions tables or the one or more long-history prediction tables.

10. The apparatus of claim 9, wherein the prediction circuitry is configured to prioritise a hit in the one or more long-history prediction tables over a hit in the one or more short-history prediction table for generating the subsequent prediction.

11. The apparatus of claim 9, wherein the state update circuitry is configured to apply the divergence-triggered update to the preliminary entry in the one or more short-history prediction tables.

12. The apparatus of claim 9, wherein in response to determining an indication that the subsequent prediction is incorrect and that the divergence-triggered update condition is also satisfied,
the state update circuitry is configured to apply both of:
the divergence-triggered update to the preliminary entry, and
a further misprediction-triggered update to the subsequent entry.

13. The apparatus of claim 1, wherein
the prediction circuitry comprises a perceptron predictor and the set of prediction state data comprises a plurality of weights;
the prediction circuitry is configured to generate the preliminary prediction by computing a prediction value based on a subset of the plurality of weights; and
the prediction circuitry is configured to generate the subsequent prediction by computing a prediction value based on the plurality of weights.

14. The apparatus of claim 1, wherein the state update circuitry is configured to apply the divergence-triggered update before an actual outcome associated with the given memory address has been determined.

15. The apparatus of claim 1, wherein the state update circuitry is configured to apply the divergence-triggered update after a determination of an actual outcome associated with the given memory address.

16. The apparatus of claim 15, wherein the divergence-triggered update condition being satisfied is further dependent on the preliminary prediction being different to the actual outcome.

17. A system comprising:
the apparatus of claim 1, implemented in at least one packaged chip;
at least one system component; and
a board;
wherein the at least one packaged chip and the at least one system component are assembled on the board.

18. A chip-containing product comprising the system of claim 17, wherein the system is assembled on a further board with at least one other product component.

19. A method comprising:
maintaining a set of prediction state data;
generating, in a preliminary pipeline stage, a preliminary prediction associated with a given memory address in dependence on a subset of the prediction state data and to provide the preliminary prediction for use by at least one other component, and
generating, in a subsequent pipeline stage, a subsequent prediction associated with the given memory address in dependence on the set of the prediction state data;
causing, in response to a determination that the subsequent prediction is different from the preliminary prediction, the at least one other component to use the subsequent prediction instead of the preliminary prediction; and
applying, in response to detecting a divergence-triggered update condition being satisfied, a divergence-triggered update to the subset of the prediction state data used to generate the preliminary prediction, wherein the divergence-triggered update condition being satisfied is dependent on the subsequent prediction being different from the preliminary prediction.

20. A non-transitory computer-readable medium storing computer-readable code for fabrication of an apparatus comprising:
prediction state storage circuitry to maintain a set of prediction state data;
prediction circuitry configured to:
in a preliminary pipeline stage, generate a preliminary prediction associated with a given memory address in dependence on a subset of the prediction state data and to provide the preliminary prediction for use by at least one other component, and
in a subsequent pipeline stage, generate a subsequent prediction associated with the given memory address in dependence on the set of the prediction state data;
overriding circuitry responsive to a determination that the subsequent prediction is different from the preliminary prediction to cause the at least one other component to use the subsequent prediction instead of the preliminary prediction; and
state update circuitry configured to apply, in response to detecting a divergence-triggered update condition being satisfied, a divergence-triggered update to the subset of the prediction state data used to generate the preliminary prediction, wherein the divergence-triggered update condition being satisfied is dependent on the subsequent prediction being different from the preliminary prediction.
